(19) United States
(12) Patent Application Publication
(10) Pub. No.: US 2019/0026028 A1
(43) Pub. Date: Jan. 24, 2019

(54) MINIMIZING PERFORMANCE DEGRADATION DUE TO REFRESH OPERATIONS IN MEMORY SUB-SYSTEMS

(71) Applicant: QUALCOMM Incorporated, San Diego, CA (US)

(72) Inventors: Dexter Tamio CHUN, San Diego, CA (US); Jungwon SUH, San Diego, CA (US); Michael Hawjing LO, San Diego, CA (US)

(21) Appl. No.: 15/658,370

(22) Filed: Jul. 24, 2017

(51) Int. Cl. G06F 3/06; G11C 11/406; G11C 11/4094

(52) U.S. Cl. CPC G06F 3/0611; G11C 11/40603; G11C 11/40618; G06F 3/0673; G11C 11/4094; G06F 3/0659; G11C 11/40626

(57) ABSTRACT

Disclosed are techniques for minimizing performance degradation due to refresh operations in a dynamic volatile memory sub-system. In an aspect, a refresh scheduler coupled to the dynamic volatile memory sub-system generates a batch memory refresh command comprising an identification of a plurality of rows of each of one or more banks of the dynamic volatile memory sub-system to refresh, and issues the batch memory refresh command to the dynamic volatile memory sub-system.

### INTRODUCTION

Aspects of this disclosure relate generally to minimizing performance degradation due to refresh operations in memory sub-systems.

Advances in technology have resulted in smaller and more powerful computing devices. For example, a variety of electronic devices, including wireless telephones such as mobile and smart phones, tablets and laptop computers, are small, lightweight, and easily carried by users. These devices can communicate voice and data packets over wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing capabilities.

Electronic devices often include a dynamic random access memory (DRAM) sub-system, one of the most widely used types of computer memory. A DRAM sub-system may spend a substantial amount of time in a power saving mode (e.g., a sleep mode or a standby mode). Electronic devices using a DRAM sub-system may use “refresh” operations to keep the contents of the DRAM refreshed during such a power saving mode. Refresh is the process of periodically reading information from an area of DRAM (e.g., a row) and immediately rewriting the read information to the same area without modification, for the purpose of preserving the information. Refresh is a background maintenance process that occurs during the operation of a DRAM sub-system, and in fact, is a defining characteristic of this class of memory.

Refresh is a necessary yet undesirable feature of DRAM that consumes additional power and degrades performance This is particularly problematic at higher temperatures because the refresh rate must be increased to compensate for the leakage and rapid cell voltage decline of the DRAM sub-system that occurs at higher temperatures. Increasing the refresh rate consumes more time and therefore reduces the amount of time that the DRAM sub-system can spend carrying mission-mode traffic. As such, the bandwidth of the DRAM sub-system is inversely related to the temperature of the DRAM sub-system.

Additionally, as the memory density of the DRAM sub-system increases, all else being the same, there will be a proportional increase in the amount of refresh needed and a similar degradation to mission-mode traffic. As such, it is desirable to minimize performance degradation due to refresh operations in a DRAM sub-system.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a method for minimizing performance degradation due to refresh operations in a dynamic volatile memory sub-system includes generating, by a refresh scheduler coupled to the dynamic volatile memory sub-system, a batch memory refresh command comprising an identification of a plurality of rows of each of one or more banks of the dynamic volatile memory sub-system to refresh, and issuing, by the refresh scheduler, the batch memory refresh command to the dynamic volatile memory sub-system.

In an aspect, an apparatus for minimizing performance degradation due to refresh operations includes a dynamic volatile memory sub-system having one or more banks and configured to receive a batch memory refresh command, wherein the batch memory refresh command identifies a plurality of rows of each of the one or more banks to refresh, and further configured to refresh the plurality of rows of each of the one or more banks based on the batch memory refresh command

In an aspect, an apparatus for minimizing performance degradation due to refresh operations in a dynamic volatile memory sub-system includes a refresh scheduler coupled to the dynamic volatile memory sub-system, the refresh scheduler configured to: generate a batch memory refresh command comprising an identification of a plurality of rows of each of one or more banks of the dynamic volatile memory sub-system to refresh; and issue the batch memory refresh command to the dynamic volatile memory sub-system.

In an aspect, a non-transitory computer-readable medium storing computer-executable instructions for minimizing performance degradation due to refresh operations in a dynamic volatile memory sub-system includes computer-executable instructions comprising at least one instruction instructing a refresh scheduler coupled to the dynamic volatile memory sub-system to generate a batch memory refresh command comprising an identification of a plurality of rows of each of one or more banks of the dynamic volatile memory sub-system to refresh and at least one instruction instructing the refresh scheduler to issue the batch memory refresh command to the dynamic volatile memory sub-system.

In an aspect, an apparatus for minimizing performance degradation due to refresh operations in a dynamic volatile memory sub-system includes a means for scheduling refresh commands coupled to the dynamic volatile memory sub-system, the means for scheduling refresh commands configured to: generate a batch memory refresh command comprising an identification of a plurality of rows of each of one or more banks of the dynamic volatile memory sub-system to refresh and issue the batch memory refresh command to the dynamic volatile memory sub-system.

Other objects and advantages associated with the aspects disclosed herein will be apparent to those skilled in the art based on the accompanying drawings and

### DETAILED DESCRIPTION

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates an exemplary system according to at least one aspect of the disclosure.

FIG. 2 illustrates an exemplary method for determining whether to utilize normal or batched refresh commands according to at least one aspect of the disclosure.

FIG. 3 illustrates an example of the performance improvement realized by the batch refresh mode of the present disclosure.

FIG. 4 illustrates an exemplary normal refresh command truth table and an exemplary batch refresh command truth table according to at least one aspect of the disclosure.

FIG. 5 is a table illustrating improvements provided by the batch refresh commands of the present disclosure.

FIG. 6 is a flow diagram illustrating an example method of minimizing performance degradation due to refresh operations in a dynamic volatile memory sub-system.

### DETAILED DESCRIPTION

Disclosed are techniques for minimizing performance degradation due to refresh operations in a dynamic volatile memory sub-system. In an aspect, a refresh scheduler coupled to the dynamic volatile memory sub-system generates a batch memory refresh command comprising an identification of a plurality of rows of each of one or more banks of the dynamic volatile memory sub-system to refresh, and issues the batch memory refresh command to the dynamic volatile memory sub-system.

More specific aspects of the disclosure are provided in the following description and related drawings directed to various examples provided for illustration purposes. Alternate aspects may be devised without departing from the scope of the disclosure. Additionally, well-known aspects of the disclosure may not be described in detail or may be omitted so as not to obscure more relevant details.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., Application Specific Integrated Circuits (ASICs)), by program instructions being executed by one or more processors, or by a combination of both. In addition, for each of the aspects described herein, the corresponding form of any such aspect may be implemented as, for example, “logic configured to” perform the described action.

As noted above, it is desirable to minimize performance degradation due to refresh operations in a DRAM sub-system. Existing methods to reduce the amount of time spent during refresh include per-bank refresh and pull-in refresh. In a per-bank refresh scheme, the DRAM is sub-divided into multiple “banks” and refreshed one bank at a time. During such a refresh operation, the one or more banks undergoing refresh are unavailable for reading and writing. For example, a first bank (e.g., bank “A”) can be refreshed while a second bank (e.g., bank “B”) is carrying traffic. However, this approach is highly traffic dependent and favors data that is uniformly distributed across all banks. For data that is not well distributed across all banks, “hotspots” of bank traffic can occur, which can result in even worse performance degradation. When such degradation occurs, the techniques described herein can help improve the performance of per-bank refresh.

Pull-in refresh is another existing method to reduce the amount of time spent during refresh. In a pull-in refresh scheme, refresh commands are issued back-to-back. This allows the memory controller to issue two or more refresh commands sequentially. While an improvement, pull-in refresh would benefit further by eliminating the overhead associated with issuing and processing multiple refresh commands, as disclosed further herein.

As such, there remains a continued need to minimize performance degradation due to refresh operations in a DRAM sub-system. Accordingly, in an aspect, to improve performance in a DRAM sub-system, multiple refresh commands can be bundled together into a single batch refresh command In that way, instead of issuing a sequence of refresh commands to the DRAM sub-system to cause it to perform a corresponding sequence of refresh operations, as in a pull-in refresh scheme, a single batch refresh command is used to invoke multiple refresh operations. The DRAM sub-system can internally reduce and parallelize refresh overhead because it is working on a batch of multiple operations, which increases the available time for reading and writing.

In addition, the system-on-chip (SoC) can selectively enable when to use batch refresh based on whether high bandwidth and/or low latency is currently requested/needed. More specifically, the SoC can disable batch refresh under normal bandwidth conditions (when high bandwidth is not requested/needed) and/or under low latency conditions (when latency-critical performance is requested/needed).

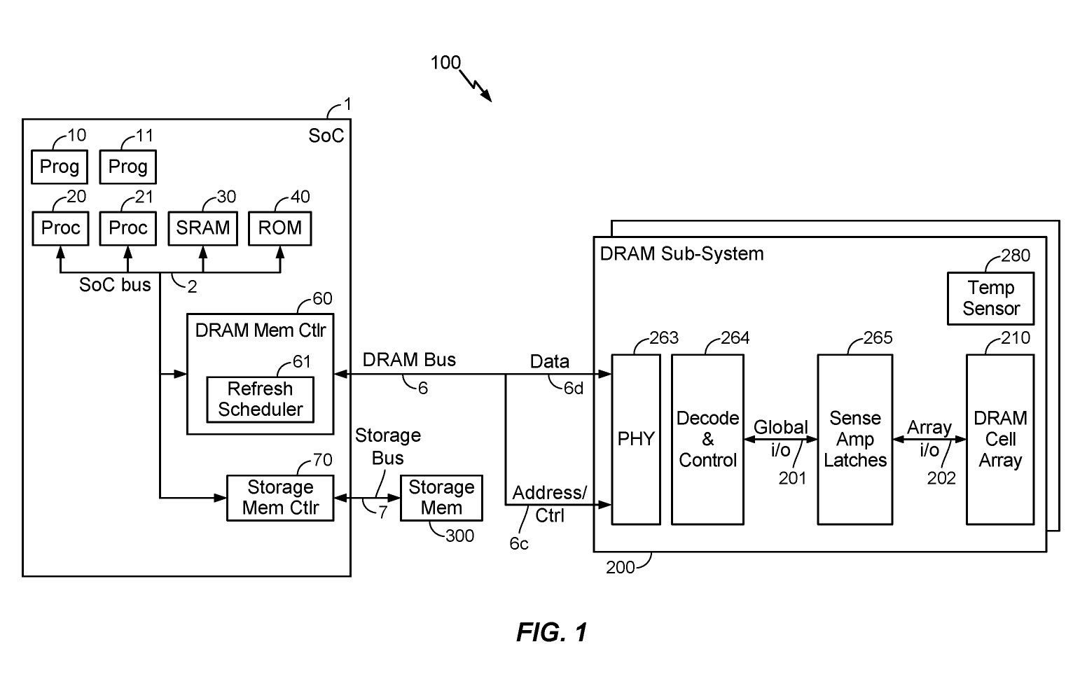

FIG. 1 illustrates an exemplary system 100 comprising an SoC 1 and a DRAM sub-system 200 according to at least one aspect of the disclosure. The SoC 1 includes a DRAM memory controller 60, a storage memory controller 70, a static random access memory (SRAM) 30, a read-only memory (ROM) 40, a processor 20, and a processor 21 communicatively coupled over a SoC bus 2. The DRAM memory controller 60 includes a refresh scheduler 61. The refresh scheduler 61 includes logic (e.g., circuits) that determines when to issue refresh commands and, as will be described further herein, whether to issue batch refresh commands or “normal” (i.e., not batched) refresh commands, and/or generates the refresh commands to send to the DRAM sub-system 200.

The storage memory controller 70 is communicatively coupled to storage memory 300 over a storage bus 7. The storage memory 300 may be any type of non-volatile memory known in the art, such as flash memory, electrically erasable programmable read-only memory (EEPROM), a solid state drive (SSD), a hard disk drive (HDD), and the like.

A program 10 is running on the processor 20 and a program 11 is running on the processor 21. The programs 10 and 11 may be separately executing programs/applications, different executable threads of the same program, different executable objects, or any other executable code, as is known in the art. The processors 20 and 21 may be ASICs, field programmable gate arrays (FPGAs), digital signal processors (DSPs), microcontrollers, microprocessors, central processing units, graphics processing units, video processing units, neural processing units, network routing processors, communication processors, MODEMs, separate cores of a single processor, or any other type of processing device known in the art that may be included in an SoC. In addition, although FIG. 1 illustrates two processors, as will be appreciated, there may be more or fewer than two processors, and the example of two processors is merely for illustration purposes.

The typical DRAM sub-system 200 includes a physical layer (PHY) module 263, a decode and control module 264 communicatively coupled to a sense amplifier and latches module (illustrated as “Sense Amp Latches”) 265 over a global input/output (i/o) interface 201, a DRAM cell array 210 communicatively coupled to the “sense amp latches” module 265 over an array input/output interface 202, and a temperature sensor 280. The DRAM sub-system 200 is communicatively coupled to the SoC 1 over a DRAM bus 6. The DRAM bus 6 carries data 6d and address/control information 6c to the PHY module 263. As illustrated in FIG. 1, there may be multiple DRAM sub-systems 200 coupled to the SoC 1 over the DRAM bus 6. Note that although the DRAM sub-system 200 is illustrated as separate from the SoC 1, as will be appreciated, the DRAM sub-system 200 may be a component of the SoC 1. In addition, the processors 20 and 21 may be referred to as “clients” of the DRAM sub-system 200.

The DRAM cell array 210 may be organized into multiple banks and/or multiple bank groups (e.g., 2, 4, or 8 bank groups of 4 or 8 banks each). Each bank includes addressable memory locations (e.g., a hierarchy of rows, columns, bits, etc.) that store data. Addresses may consist of a bank address portion, a row address portion, and a column address portion. The bank address portion may consist of multiple bits to select a particular memory bank (e.g., 4 bits to select from 16 banks). The row address portion may similarly consist of multiple bits to identify a particular row of a memory bank (e.g. 13 bits to select from 8192 rows). The column address portion may similarly consist of multiple bits (e.g., 9 bits) to select a starting address within the chosen row to perform a read/write burst transaction. Alternatively, the DRAM cell array 210 may be structured as a relational table of rows and columns

Typically, to read or write data, the row containing the address to be read/written must first be retrieved and stored in the sense amplifier latches 265, which is known as “activation.” Activation is performed for any bank that will be read/written. Once a row in a bank is activated, the bank is now “open” and the sense amplifier latches 265 holds the row (sometimes also referred to as a “page”) that was requested to be activated. While open, any number of reads or writes to anywhere (e.g., any column address) within the row may occur. When reads/writes to the open row are done, or when a different row within the same bank is to be accessed, then the row is “closed” by having the sense amplifier latches 265 transfer their data back into the cell array 210, which is referred to as “precharging.” Only after precharging the first row is complete can activation of the second row commence.

Refresh is the act of opening a row, then immediately precharging it; the sense amplifier latches 265 receive the row contents and in doing so restore the full voltage and electrical charge of every bit in the row when the precharge occurs. Refresh may be done on individual banks or on all banks. Since there are multiple rows in a bank (e.g., 8192), a circular refresh address counter in the DRAM sub-system 200 increments upon receipt of the SoC's refresh command to ensure that every row is refreshed. With batch refresh, multiple rows (e.g., 2× or 4× in all banks or in a single (per) bank) can be refreshed using a single command The single batch refresh command results in multiple rows being refreshed and the corresponding refresh address counter value being increased.

In an aspect, the refresh scheduler 61 may include precharge command logic to manage the precharging of portions of the DRAM cell array 210. More specifically, the refresh scheduler 61 may generate one or more precharge commands in conjunction with one or more refresh commands to place one or more cells of the DRAM cell array 210 in a refreshed state.

Note that although FIG. 1 illustrates a DRAM sub-system 200, the techniques described herein may be implemented in any dynamic volatile memory (e.g. eDRAM) that utilizes refresh operations. DRAM and the DRAM sub-system 200 are merely an example of a dynamic volatile memory sub-system. Further, although FIG. 1 illustrates a specific arrangement of the SoC 1 and the DRAM sub-system 200, as will be appreciated, this arrangement is exemplary, and other arrangements are possible, as is known in the art.

Further, as will be appreciated, the functionality of the modules illustrated in FIG. 1 may be implemented in various ways consistent with the teachings herein. In some designs, the functionality of these modules may be implemented as one or more electrical components (e.g., integrated circuits). In some designs, the functionality of these modules may be embodied as executable software modules. Thus, the functionality of different modules may be implemented, for example, as different subsets of an integrated circuit, as different subsets of a set of software modules, or a combination thereof. Also, it will be appreciated that a given subset (e.g., of an integrated circuit and/or of a set of software modules) may provide at least a portion of the functionality for more than one module.

Programs 10 and 11 running on processors 20 and 21 may need different performance levels from the DRAM sub-system 200. Performance corners may be low bandwidth, high bandwidth, latency-critical, latency-noncritical, and combinations thereof. The DRAM memory controller 60 receives indications of the desired performance level from the processors 20 and 21 and uses this information to select the operating frequency of refreshes in the DRAM sub-system 200. The refresh scheduler 61 also uses the requested performance level and the temperature from the temperature sensor 280 to determine whether to utilize normal refresh or batch refresh.

In an aspect, to indicate the desired performance level, the processors 20 and 21 can “vote” to request a needed bandwidth or request a needed latency periodically or upon event changes. The votes from the processors 20 and 21 may be an arbitrary number that represents each processor's need for bandwidth and for latency. The votes may be weighted (taking into account any priority of one processor versus another processor, and also normalizing them depending on the number of actively voting processors) and then summed to establish a bandwidth performance index and a separate latency performance index that can be used to determine the DRAM refresh mode (either normal or batched). The summing may be performed by the hardware adder and rounding/truncation, or alternatively by a lookup table or by the firmware. If performed by a lookup table or the firmware, versatility may be improved by allowing more complex functions (e.g., quadratic, log, etc.) to be incorporated in the sum, and also to allow changes/updates to the lookup table or the firmware. Note that these indices may also be used for other purposes, such as clock frequency and voltage regulation.

If the bandwidth performance index exceeds a threshold, then high bandwidth (e.g., operating the DRAM sub-system 200 at a faster clock frequency and/or enabling additional memory channels) is being requested. If the latency-critical index exceeds a threshold (or alternatively if the raw latency index falls below a threshold), then low latency (e.g., operating the DRAM sub-system 200 at a faster clock frequency and/or operating the DRAM sub-system 200 using lower latency settings) is being requested. Temperature sensors 280 in the DRAM sub-system 200 may similarly be compared against a temperature threshold. The temperature of the DRAM sub-system 200 is important because the DRAM sub-system 200 is refreshed more often at higher temperatures. The indices may be prioritized so that latency-critical performance has priority over high bandwidth performance and high bandwidth performance has priority over temperature. Refresh can starve the read/write traffic during the precharge, refresh, and activate operations, so it is beneficial to monitor and react to the latency, bandwidth, and temperature indices as described.

Latency, bandwidth, and temperature are the most influential factors in determining whether to utilize normal or batched refresh. However, there may be secondary metrics that can provide further improvement, such as the hit rate of internal caches (e.g., a high cache hit rate will reduce the bandwidth and/or latency vote), the battery state of charge (e.g., a low state of charge will reduce the bandwidth and/or latency vote), the overall system temperature (e.g., a high temperature at one or multiple other locations indicating that thermal capacity has been reached will reduce the bandwidth and/or latency vote), and the like. These factors can be monitored and taken into consideration when determining whether to utilize normal or batched refresh. Alternatively, for lower complexity systems, fewer indices may be implemented in order to minimize cost. For example, the latency index alone could be used to select between normal or batched refresh.

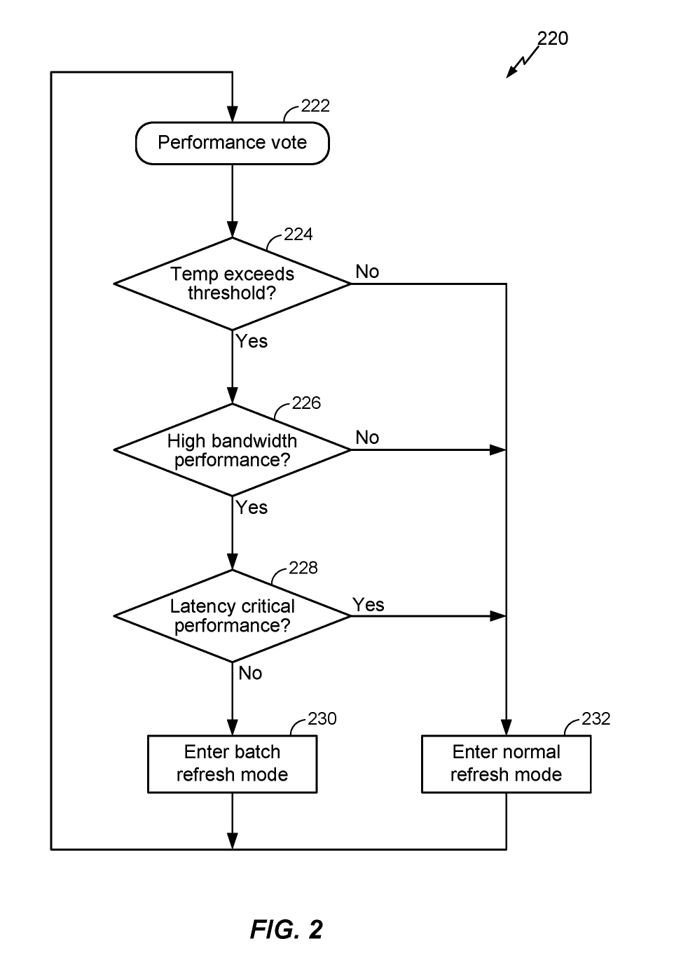

FIG. 2 illustrates an exemplary method 220 for determining whether to utilize normal or batched refresh commands according to at least one aspect of the disclosure. The method 220 may be performed by the refresh scheduler 61. At 222, the refresh scheduler 61 receives one or more performance votes from one or more of the processors 20 and 21. For example, where the processors 20 and 21 each vote at the same periodic interval, the refresh scheduler 61 may receive a vote from each processor 20 and 21 at 222. However, where the processors 20 and 21 vote based on the occurrence of an event, the refresh scheduler 61 may receive a vote from processor 20 at 222 and a vote from processor 21 at a different time. Either way, as the refresh scheduler 61 receives votes (e.g., at 222), the incoming votes are weighted and added to the current values of the bandwidth performance index and the latency performance index.

A performance vote may either be a vote to increase bandwidth, decrease bandwidth, increase latency, or decrease latency. Thus, for example, a processor 20 or 21 may vote to decrease latency during a latency-critical period of its execution, and then vote to increase latency during a non-latency-critical period of its execution. In this way, there is no need to reset the bandwidth performance index or the latency performance index. Alternatively, where a processor 20 or 21 only votes to increase bandwidth or decrease latency, the bandwidth performance index and the latency performance index may be reset periodically or upon termination of execution of the program 10 or 11, for example.

At 224, the refresh scheduler 61 determines whether or not the temperature of the DRAM sub-system 200 reported by the temperature sensor 280 exceeds a threshold. If it does, then at 226, the refresh scheduler 61 determines whether or not high bandwidth performance has been requested. In an aspect, if the bandwidth performance index exceeds a threshold (after the vote(s) received at 222 is/are weighted and added together), then high bandwidth performance is being requested. If high bandwidth performance is being requested, then at 228, the refresh scheduler 61 determines whether or not latency-critical performance has been requested. In an aspect, if the latency performance index exceeds a threshold (after the vote(s) received at 222 is/are weighted and added together), then latency-critical performance is being requested. If latency-critical performance is not being requested, then at 230, the refresh scheduler 61 uses the batch refresh mode. If, however, the temperature does not exceed the threshold, high bandwidth performance is not being requested, or latency-critical performance is being requested, then at 232, the refresh scheduler 61 uses the normal refresh mode.

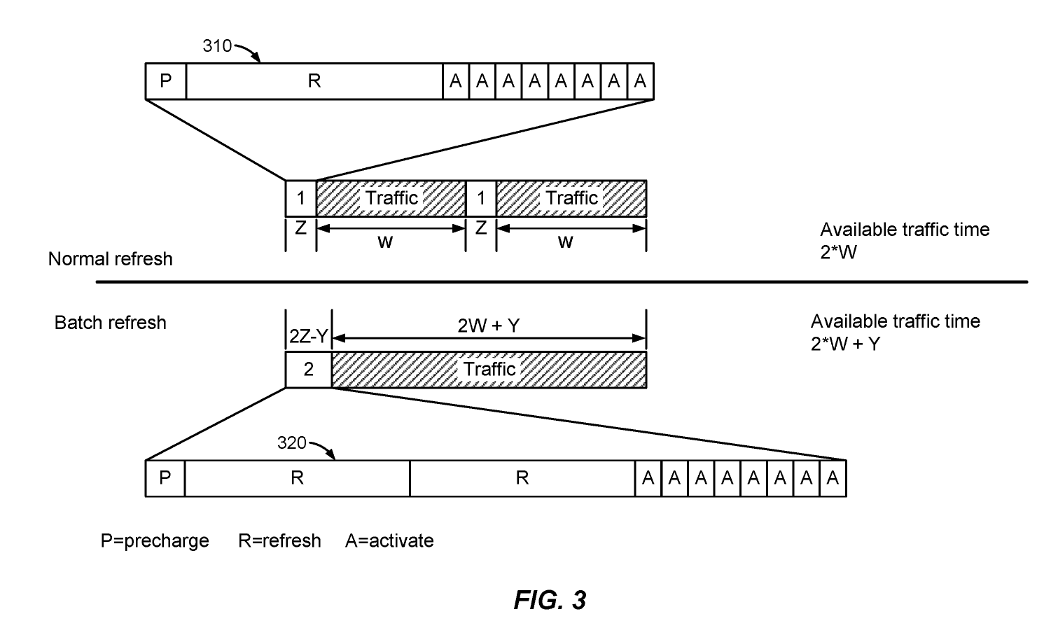

FIG. 3 illustrates an example of the performance improvement realized by the batch refresh mode of the present disclosure. As illustrated in FIG. 3, a normal refresh command 310 includes a precharge (P) field, a refresh (R) field identifying a portion (e.g., a row of a bank or the same row of each bank) of the DRAM cell array 210 to be refreshed, and a plurality of activate (A) fields. A refresh command 310 issued by the refresh scheduler 61 and transmitted over the DRAM bus 6 along with internal P, R, and A processing within the DRAM sub-system 200 consumes an amount of time equivalent to a data length of Z, and is followed by data traffic transmitted over the DRAM bus 6 having a data length of W. Using normal refresh commands 310 to identify two portions of the DRAM cell array 210 to be refreshed occupies a data length of Z+Z, or 2Z.

In contrast, a batch refresh command 320 to identify the same two portions of the DRAM cell array 210 as the two normal refresh commands 310 includes a precharge (P) field, the two refresh (R) fields identifying the two portions of the DRAM cell array 210 to be refreshed, and the plurality of activate (A) fields. The equivalent data length of such a batch refresh command 320 is 2 Z-Y, where Y is the length of the precharge (P) field and the plurality of activate (A) fields. More specifically, while the two normal refresh commands each require the overhead of a precharge (P) field and the plurality of activate (A) fields for each refresh (R) field, because it is a single refresh command, the batch refresh command 320 only includes the overhead of one precharge (P) field and one plurality of activate (A) fields. Thus, despite having two refresh (R) fields, the batch refresh command 320 has the same overhead as a single normal refresh command 310. As illustrated in FIG. 3, by issuing the batch refresh command 320 with the two refresh (R) fields, the amount of traffic on the DRAM bus 6 is increased by Y.

More broadly speaking, a batch refresh command, such as batch refresh command 320, has the same overhead as a normal refresh command, such as normal refresh command 310, regardless of the number of refresh (R) fields in the batch refresh command This increases the bandwidth of the DRAM bus 6 by the overhead that would otherwise be required by the corresponding number of normal refresh commands

Note that the precharge (P) and activate (A) fields are not always present; they are generated in response to the need to read/write rows in the DRAM sub-system 200 (typically proportional to the amount of traffic on the DRAM bus 6).

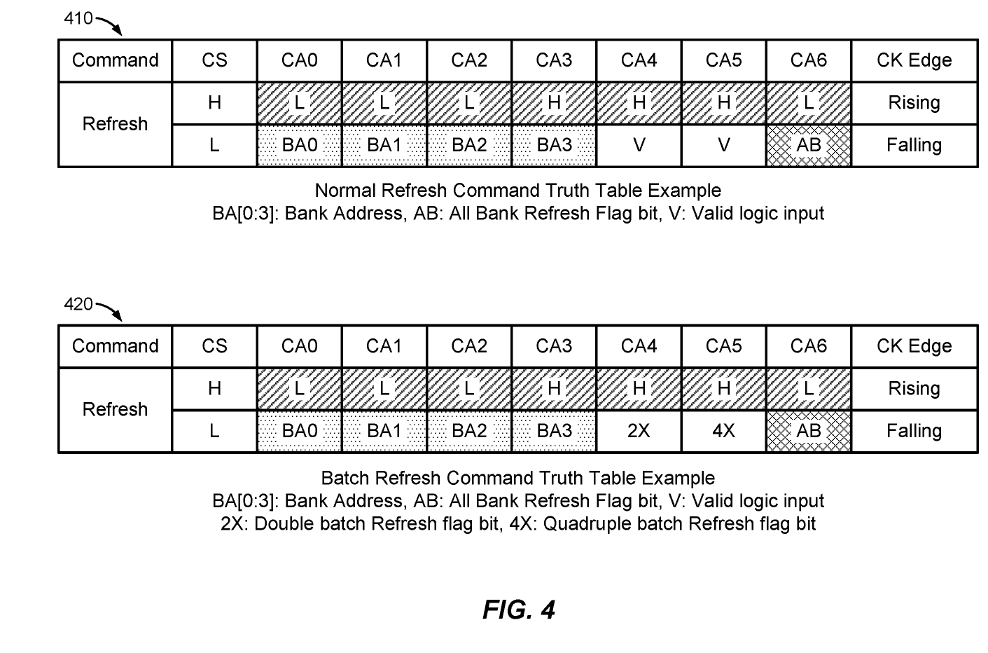

FIG. 4 illustrates an exemplary normal refresh command truth table 410 and an exemplary batch refresh command truth table 420 according to at least one aspect of the disclosure. In FIG. 4, “H” indicates a set bit (often referred to as a “1”), “L” indicates a not set bit (often referred to as a “0”), “V” indicates either a set bit or a not set bit, “X” is “1,” “0,” or invalid (i.e., neither 1 nor 0), “CS” represents “chip select,” and “CA” represents “command address.”

With reference to FIG. 4, if the “2×” or “4×” batch refresh flag bits in the batch refresh command truth table 420 are non-zero, the batch refresh operations are executed per the batch refresh command The values “2×” and “4×” indicate the number of rows in a bank of the DRAM cell array 210 to refresh. The refresh scheduler 61 can refresh, for example, one, two, or four rows of one bank, multiple banks, or all banks. More specifically, the refresh scheduler 61 can issue a batch refresh command to refresh one, two, or four rows of one bank, one, two, or four rows of each bank of a group of banks, or one, two, or four rows of all banks.

For example, referring to FIG. 4, where the all bank refresh flag bit (AB) and the 2× batch refresh flag bit are set (H) and the 4× batch refresh flag bit is not set (L), the batch refresh command indicates that the DRAM sub-system 200 should perform a “double batch all bank” refresh operation (i.e., two portions (e.g., rows) of each bank of the DRAM cell array 210). As another example, where the all bank refresh flag bit (AB) and the 4× batch refresh flag bit are set (H) and the 2× batch refresh flag bit is not set (L), the batch refresh command indicates that the DRAM sub-system 200 should perform a “quadruple batch all bank” refresh operation (i.e., four portions (e.g., rows) of each bank of the DRAM cell array 210).

As yet another example, still referring to FIG. 4, where the all bank refresh flag bit (AB) and the 4× batch refresh flag bit are not set (L) and the 2× batch refresh flag bit is set (H), the batch refresh command indicates that the DRAM sub-system 200 should perform a “double batch per-bank” refresh operation. More specifically, the binary value using bank addresses BA3, BA2, BA1, and BA0 contained in batch refresh command 420 will indicate the particular bank being refreshed (e.g., the binary string “1111” would indicate bank 15, and “0000” would indicate bank 0). For 2×, two rows will be refreshed in one batch.

As another example, again referring to FIG. 4, where the all bank refresh flag bit (AB) and the 2× batch refresh flag bit are not set (L) and the 4× batch refresh flag bit is set (H), the batch refresh command indicates that the DRAM sub-system 200 should perform a “quadruple batch per-bank” refresh operation. In this case, the binary value using bank addresses BA3, BA2, BA1, and BA0 contained in batch refresh command 420 will indicate the particular bank being refreshed (e.g., the binary string “1111” would indicate bank 15, and “0000” would indicate bank 0). For 4×, four rows will be refreshed in one batch.

Note that the truth tables shown in FIG. 4 are one example of the command bits assignment. As will be appreciated, other permutations of bits may be chosen instead. For example, the two bits 2× and 4× could instead map to 4× and 8×, or could be any mapping that corresponds to any multiple of refreshes performed in a single batch. Also, their position within the batch refresh command 420 and decoding (“H” versus “L”) may be moved or changed to accommodate command truth tables with more or fewer CA bits (e.g., 5 CA bits versus 7 CA bits in FIG.4).

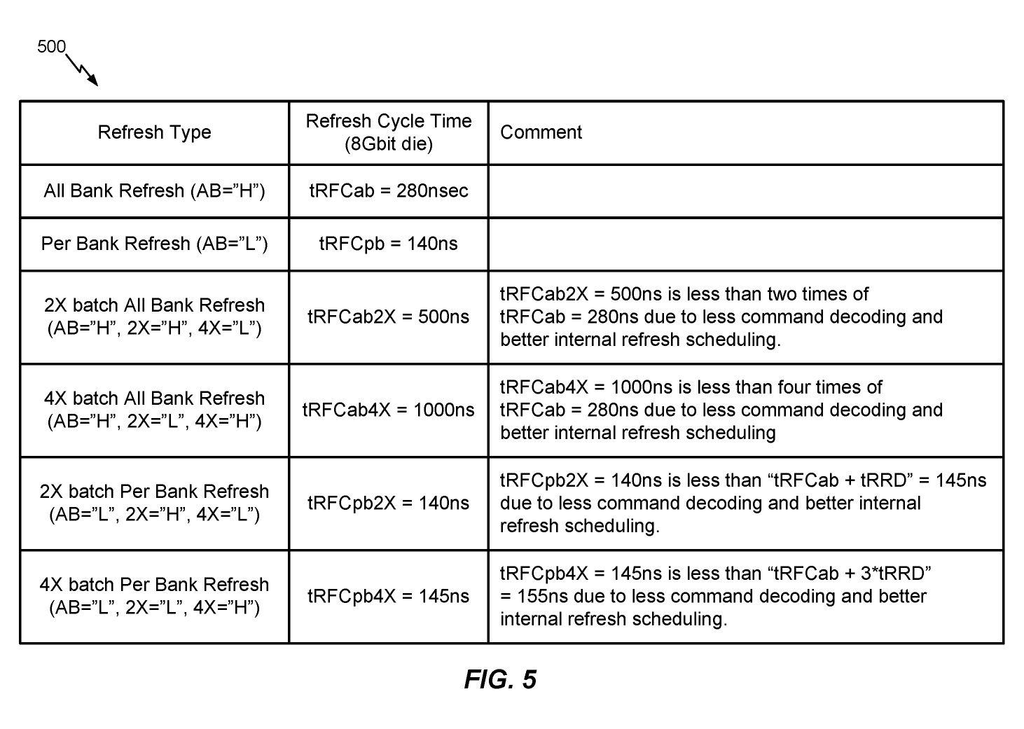

FIG. 5 is a table 500 illustrating improvements provided by the batch refresh commands of the present disclosure. With reference to FIG. 5, if a 2× or 4× batch refresh operation is enabled by the refresh command, the DRAM sub-system 200 can reduce the Refresh Cycle Time (tRFC) by eliminating duplicated refresh command decoding and logic delay and improving the DRAM internal refresh scheduling without any impact on its peak refresh power or power network. For example, using existing pull-in refresh to perform two all bank refreshes (double row 1 of table 500) takes 2*280 nanoseconds (nsec), or 560 nsec, whereas using a single 2× batch all bank refresh (row 3 of table 500) takes 500 nsec, resulting in a savings of 60 nsec. Similarly, using a 4x batch all bank refresh (row 4 of table 500) takes 1000 nsec, which is a 120 nsec savings compared to pull-in four all bank refresh (quadruple row 1 of table 1), which takes 4*280 nsec.

For all bank refresh, the savings result from the elimination of command processing duplication. Further, all bank refresh savings may come with increased cost because the DRAM power network is typically designed to provide just enough power to simultaneously refresh all banks in the DRAM sub-system 200. However, for per bank refresh, savings are even greater because the DRAM sub-system 200's power network can easily handle the power demand from refreshing multiple rows. For example, using existing pull-in refresh to perform four per bank refresh (quadruple row 2 of table 500) takes 4*140 nsec, or 560 nsec, whereas using a single 4× batch per bank refresh (row 6 of table 5) takes 145 nsec, resulting in a savings of 415 nsec. Note that these timing values are representative of what may be typical for a DRAM sub-system based on conventional DRAM internal architecture, and further improvement may be possible.

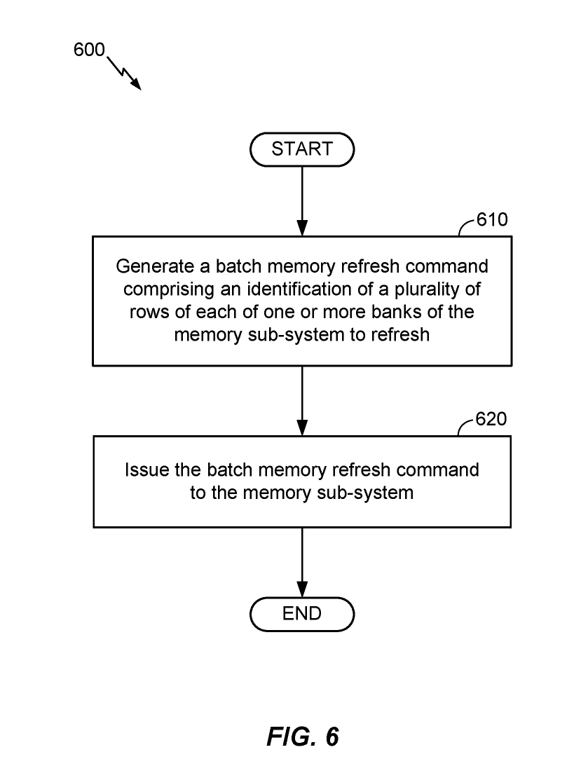

FIG. 6 is a flow diagram illustrating an example method 600 of minimizing performance degradation due to refresh operations in a dynamic volatile memory sub-system, such as the DRAM sub-system 200. The method 600 may be performed by, for example, the refresh scheduler 61.

At 610, the refresh scheduler 61 generates a batch memory refresh command (e.g., batch refresh command 320) comprising an identification of a plurality of rows (e.g., as identified by the CA4 or CA5 field of the batch refresh command truth table 420) of each of one or more banks of the dynamic volatile memory sub-system (e.g., DRAM sub-system 200) to refresh. As discussed above, the one or more banks of the dynamic volatile memory sub-system to refresh may comprise multiple banks of the dynamic volatile memory sub-system, all banks of the dynamic volatile memory sub-system, or a single bank of the dynamic volatile memory sub-system. The plurality of rows may comprise two rows or four rows.

At 620, the refresh scheduler 61 issues the batch memory refresh command to the dynamic volatile memory sub-system, which, where the dynamic volatile memory sub-system corresponds to the DRAM sub-system 200, refreshes the DRAM cell array 210 as instructed.

In an aspect, generating the batch memory refresh command at 610 may be based on a temperature of the dynamic volatile memory sub-system being greater than a temperature threshold, high bandwidth performance being requested, or latency-critical performance not being requested, as discussed above with reference to FIG. 3. In an aspect, the refresh scheduler 61 may receive, from one or more clients (e.g., processors 20 and 21) of the dynamic volatile memory sub-system, one or more votes indicating whether or not high bandwidth performance is requested, calculate a bandwidth performance index by summing the one or more votes from the one or more clients, and determine that high bandwidth performance is being requested based on the bandwidth performance index being greater than a high bandwidth threshold.

In an aspect, the refresh scheduler 61 may receive, from one or more clients of the dynamic volatile memory sub-system, one or more votes indicating whether or not latency-critical performance is being requested, calculate a latency performance index by summing the one or more votes from the one or more clients, and determine that latency-critical performance is not being requested based on the latency performance index being less than a low latency threshold. As discussed above with reference to FIG. 3, latency-critical performance not being requested may have a higher priority than high bandwidth performance being requested, and high bandwidth performance being requested may have a higher priority than the temperature of the dynamic volatile memory sub-system being greater than the temperature threshold.

It should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner Also, unless stated otherwise a set of elements may comprise one or more elements. In addition, terminology of the form “at least one of A, B, or C” or “one or more of A, B, or C” or “at least one of the group consisting of A, B, and C” used in the description or the claims means “A or B or C or any combination of these elements.” For example, this terminology may include A, or B, or C, or A and B, or A and C, or A and B and C, or 2A, or 2B, or 2C, and so on.

In view of the descriptions and explanations above, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Accordingly, it will be appreciated, for example, that an apparatus or any component of an apparatus may be configured to (or made operable to or adapted to) provide functionality as taught herein. This may be achieved, for example: by manufacturing (e.g., fabricating) the apparatus or component so that it will provide the functionality; by programming the apparatus or component so that it will provide the functionality; or through the use of some other suitable implementation technique. As one example, an integrated circuit may be fabricated to provide the requisite functionality. As another example, an integrated circuit may be fabricated to support the requisite functionality and then configured (e.g., via programming) to provide the requisite functionality. As yet another example, a processor circuit may execute code to provide the requisite functionality.

Moreover, the methods, sequences, and/or algorithms described in connection with the aspects disclosed herein may be embodied directly in hardware, in a software module executed by a processor, or in a combination of the two. A software module may reside in RAM, flash memory, ROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor (e.g., cache memory).

Accordingly, it will also be appreciated, for example, that certain aspects of the disclosure can include a computer-readable medium embodying a method for minimizing performance degradation due to refresh operations in a dynamic volatile memory sub-system as described herein.

While the foregoing disclosure shows various illustrative aspects, it should be noted that various changes and modifications may be made to the illustrated examples without departing from the scope defined by the appended claims. The present disclosure is not intended to be limited to the specifically illustrated examples alone. For example, unless otherwise noted, the functions, steps, and/or actions of the method claims in accordance with the aspects of the disclosure described herein need not be performed in any particular order. Furthermore, although certain aspects may be described or claimed in the singular, the plural is contemplated unless limitation to the singular is explicitly stated.

1. A method for minimizing performance degradation due to refresh operations in a dynamic volatile memory sub-system, the method comprising:
generating, by a refresh scheduler coupled to the dynamic volatile memory sub-system, a batch memory refresh command comprising an identification of a plurality of rows of each of one or more banks of the dynamic volatile memory sub-system to refresh; and
issuing, by the refresh scheduler, the batch memory refresh command to the dynamic volatile memory sub-system.

2. The method of claim 1, wherein the one or more banks of the dynamic volatile memory sub-system to refresh comprise multiple banks of the dynamic volatile memory sub-system, all banks of the dynamic volatile memory sub-system, or a single bank of the dynamic volatile memory sub-system.

3. The method of claim 1, wherein the plurality of rows comprise two rows or four rows.

4. The method of claim 1, wherein the batch memory refresh command comprises a precharge field, the identification of the plurality of rows, and a plurality of activate fields.

5. The method of claim 1, wherein the generating the batch memory refresh command is based on a temperature of the dynamic volatile memory sub-system being greater than a temperature threshold, high bandwidth performance being requested, or latency-critical performance not being requested.

6. The method of claim 5, further comprising:
receiving, from one or more clients of the dynamic volatile memory sub-system, one or more votes indicating whether or not high bandwidth performance is requested;
calculating a bandwidth performance index by summing the one or more votes from the one or more clients; and
based on the bandwidth performance index being greater than a high bandwidth threshold, determining that high bandwidth performance is being requested.

7. The method of claim 5, further comprising:
receiving, from one or more clients of the dynamic volatile memory sub-system, one or more votes indicating whether or not latency-critical performance is being requested;
calculating a latency performance index by summing the one or more votes from the one or more clients; and
based on the latency performance index being less than a low latency threshold, determining that latency-critical performance is not being requested.

8. The method of claim 7, wherein at least one of the one or more clients comprises a processor coupled to the dynamic volatile memory sub-system.

9. The method of claim 5, wherein latency-critical performance not being requested has a higher priority than high bandwidth performance being requested, and wherein high bandwidth performance being requested has higher priority than the temperature of the dynamic volatile memory sub-system being greater than the temperature threshold.

10. The method of claim 1, wherein the dynamic volatile memory sub-system comprises a dynamic random access memory (DRAM) sub-system.

11. The method of claim 1, wherein the method is performed in a system-on-chip (SoC) coupled to the dynamic volatile memory sub-system.

12. An apparatus for minimizing performance degradation due to refresh operations, comprising:
a dynamic volatile memory sub-system having one or more banks and configured to receive a batch memory refresh command, wherein the batch memory refresh command identifies a plurality of rows of each of the one or more banks to refresh, and further configured to refresh the plurality of rows of each of the one or more banks based on the batch memory refresh command.

13. The apparatus of claim 12, further comprising
a bus; and
a host configured to provide the batch memory refresh command to the dynamic volatile memory sub-system via the bus.

14. The apparatus of claim 12, wherein the one or more banks of the dynamic volatile memory sub-system to refresh comprise multiple banks of the dynamic volatile memory sub-system, all banks of the dynamic volatile memory sub-system, or a single bank of the dynamic volatile memory sub-system.

15. The apparatus of claim 12, wherein the plurality of rows comprise two rows or four rows.

16. The apparatus of claim 12, wherein reception of the batch memory refresh command is based on a temperature of the dynamic volatile memory sub-system being greater than a temperature threshold, high bandwidth performance being requested, or latency-critical performance not being requested.

17. An apparatus for minimizing performance degradation due to refresh operations in a dynamic volatile memory sub-system, the apparatus comprising:
a refresh scheduler coupled to the dynamic volatile memory sub-system, the refresh scheduler configured to:
generate a batch memory refresh command comprising an identification of a plurality of rows of each of one or more banks of the dynamic volatile memory sub-system to refresh; and
issue the batch memory refresh command to the dynamic volatile memory sub-system.

18. The apparatus of claim 17, further comprising
a bus; and
the dynamic volatile memory sub-system configured to receive the batch memory refresh command from the refresh scheduler via the bus.

19. The apparatus of claim 18, wherein the one or more banks of the dynamic volatile memory sub-system to refresh comprise multiple banks of the dynamic volatile memory sub-system, all banks of the dynamic volatile memory sub-system, or a single bank of the dynamic volatile memory sub-system.

20. The apparatus of claim 18, wherein the plurality of rows comprise two rows or four rows.

21. The apparatus of claim 18, wherein the batch memory refresh command comprises a precharge field, the identification of the plurality of rows, and a plurality of activate fields.

22. The apparatus of claim 18, wherein the refresh scheduler generates the batch memory refresh command based on a temperature of the dynamic volatile memory sub-system being greater than a temperature threshold, high bandwidth performance being requested, or latency-critical performance not being requested.

23. The apparatus of claim 22, wherein the refresh scheduler is further configured to:
receive, from one or more clients of the dynamic volatile memory sub-system, one or more votes indicating whether or not high bandwidth performance is requested;
calculate a bandwidth performance index by summing the one or more votes from the one or more clients; and
based on the bandwidth performance index being greater than a high bandwidth threshold, determine that high bandwidth performance is being requested.

24. The apparatus of claim 22, wherein the refresh scheduler is further configured to:
receive, from one or more clients of the dynamic volatile memory sub-system, one or more votes indicating whether or not latency-critical performance is being requested;
calculate a latency performance index by summing the one or more votes from the one or more clients; and
based on the latency performance index being less than a low latency threshold, determine that latency-critical performance is not being requested.

25. The apparatus of claim 24, wherein at least one of the one or more clients comprises a processor coupled to the dynamic volatile memory sub-system.

26. The apparatus of claim 22, wherein latency-critical performance not being requested has a higher priority than high bandwidth performance being requested, and wherein high bandwidth performance being requested has higher priority than the temperature of the dynamic volatile memory sub-system being greater than the temperature threshold.

27. The apparatus of claim 18, wherein the dynamic volatile memory sub-system comprises a dynamic random access memory (DRAM) sub-system.

28. The apparatus of claim 18, wherein the refresh scheduler is a component of a system-on-chip (SoC) coupled to the dynamic volatile memory sub-system.

29. An apparatus for minimizing performance degradation due to refresh operations in a dynamic volatile memory sub-system, the apparatus comprising:
a means for scheduling refresh commands coupled to the dynamic volatile memory sub-system, the means for scheduling refresh commands configured to:
generate a batch memory refresh command comprising an identification of a plurality of rows of each of one or more banks of the dynamic volatile memory sub-system to refresh; and
issue the batch memory refresh command to the dynamic volatile memory sub-system.

30. The apparatus of claim 29, wherein the one or more banks of the dynamic volatile memory sub-system to refresh comprise multiple banks of the dynamic volatile memory sub-system, all banks of the dynamic volatile memory sub-system, or a single bank of the dynamic volatile memory sub-system.
